(19) United States
(12) Patent Application Publication
(10) Pub. No.: US 2026/0181907 A1
(43) Pub. Date: Jun. 25, 2026

(54) BACK-END-OF-LINE COMPATIBLE FERROELECTRIC CAPACITIVE SYNAPTIC DEVICE STRUCTURE

(71) Applicant: Georgia Tech Research Corporation, Atlanta, GA (US)

(72) Inventor: Shimeng Yu, Atlanta, GA (US)

(21) Appl. No.: 19/309,338

(22) Filed: Aug. 25, 2025

Related U.S. Application Data
(60) Provisional application No. 63/689,226, filed on Aug. 30, 2024.

(51) Int. Cl. H10B 53/00; H10D 1/64

(52) U.S. Cl. CPC H10B 53/00; H10D 1/64

(57) ABSTRACT

The present disclosure provides a back-end-of-line (BEOL) compatible ferroelectric capacitive synaptic device comprising a first metal electrode, a ferroelectric layer disposed on the first metal electrode, a semiconductor layer disposed on the ferroelectric layer, and a second metal electrode disposed on the semiconductor layer. The semiconductor layer comprises a material compatible with a back-end-of-line fabrication thermal budget temperature. The first metal electrode and the second metal electrode completely overlap with the ferroelectric layer and the semiconductor layer sandwiched therebetween. The BEOL compatible ferroelectric capacitive synaptic device is configured to switch between a high capacitance state and a low capacitance state by applying voltage pulses between the first metal electrode and the second metal electrode to flip dipole orientation in the ferroelectric layer. The device enables multi-tier three-dimensional stacking for in-memory computing applications.

### CROSS-REFERENCE TO RELATED APPLICATIONS

This application claims the benefit of U.S. Provisional Application No. 63/689,226, titled “CAPACITIVE READ-OUT MODE FOR FERROELECTRIC FIELD EFFECT TRANSISTOR FOR CHARGE-DOMAIN IN-MEMORY COMPUTING,” filed Aug. 30, 2024, which is incorporated herein by reference in its entirety.

### FEDERALLY SPONSORED RESEARCH AND DEVELOPMENT

This invention was made with government support under Grant No. HR0011-23-3-0002 awarded by the Department of Defense/Defense Advanced Research Projects Agency (DARPA). The government has certain rights in the invention.

### FIELD OF INVENTION

The present disclosure relates to semiconductor memory devices for artificial intelligence applications, and more particularly to back-end-of-line compatible ferroelectric capacitive synaptic devices having metal-ferroelectric-semiconductor stack structures for charge-domain in-memory computing.

### BACKGROUND

Artificial intelligence and machine learning applications have experienced rapid growth across various computing platforms, from data centers to edge devices. These applications typically rely on neural network algorithms that perform computationally intensive operations involving large amounts of data. Traditional computing architectures separate processing units and memory storage, requiring frequent data transfers between these components during neural network operations. This separation creates bottlenecks in system throughput and energy efficiency as data must be continuously moved between memory and processing elements.

The data movement overhead becomes particularly pronounced in modern artificial intelligence algorithms where the size and complexity of neural network models continue to increase. Large neural networks may contain millions or billions of parameters that must be accessed repeatedly during inference and training operations. The energy consumed in transferring this data between memory and processing units often exceeds the energy used for the actual computational operations, limiting the overall efficiency of artificial intelligence systems.

In-memory computing represents an alternative approach that performs processing operations within memory arrays themselves, reducing the need for data movement between separate processing and storage components. This paradigm enables parallel execution of operations across multiple memory elements simultaneously, potentially improving both throughput and energy efficiency. Various memory technologies have been explored for in-memory computing implementations, including resistive memory devices that store information as different resistance states.

Resistive memory approaches for in-memory computing utilize the conductance values of memory elements as weights in neural network computations. These systems perform current-domain calculations where input voltages applied across resistive elements generate currents proportional to the stored conductance values. While this approach enables parallel processing capabilities, resistive memory systems consume static power whenever voltages are applied across the memory elements, as current flows continuously through the resistive paths.

Capacitive memory devices offer an alternative approach for in-memory computing that may address some limitations of resistive systems. Capacitive devices store information as different capacitance states and can perform charge-domain computations rather than current-domain operations. The charge-based approach may provide power consumption advantages since capacitive elements draw current primarily during charging and discharging transitions rather than maintaining continuous current flow.

The integration of memory devices with existing semiconductor manufacturing processes presents additional considerations for practical implementation. Back-end-of-line processing compatibility enables the fabrication of memory elements using thermal budgets that do not interfere with previously formed transistor structures. This compatibility facilitates the integration of memory arrays with complementary metal-oxide-semiconductor circuits and enables three-dimensional stacking approaches that can increase memory density without expanding device footprints.

Ferroelectric materials provide non-volatile storage capabilities through polarization switching mechanisms that can be retained without continuous power application. The integration of ferroelectric materials with semiconductor layers creates opportunities for developing memory devices with enhanced switching characteristics and improved performance metrics compared to conventional memory approaches.

### SUMMARY

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

In one aspect, a back-end-of-line compatible ferroelectric capacitive synaptic device may include a first metal electrode, a ferroelectric layer disposed on the first metal electrode, a semiconductor layer disposed on the ferroelectric layer that comprises a material compatible with a back-end-of-line fabrication thermal budget temperature, and a second metal electrode disposed on the semiconductor layer. The first metal electrode and the second metal electrode may completely overlap with the ferroelectric layer and the semiconductor layer sandwiched therebetween, and the device may be configured to switch between a high capacitance state and a low capacitance state by applying voltage pulses between the first metal electrode and the second metal electrode to flip dipole orientation in the ferroelectric layer.

In some cases, the semiconductor layer may comprise an amorphous oxide semiconductor material selected from amorphous silicon, polycrystalline silicon, indium-tungsten-oxide, indium-tin-oxide, or indium-gallium-zinc-oxide. The ferroelectric layer may comprise a doped hafnia-based material such as hafnium-zirconium-oxide or silicon-doped hafnium oxide. In the high capacitance state, capacitance between the second metal electrode and the semiconductor layer may dominate, while in the low capacitance state, capacitance between the first metal electrode and the second metal electrode may dominate.

In another aspect, a back-end-of-line compatible ferroelectric capacitive synaptic device may include a similar stack structure where the second metal electrode partially overlaps with the ferroelectric layer and the semiconductor layer, creating a reduced overlap area compared to the first metal electrode. This configuration may provide a capacitance on/off ratio greater than 1000 at zero direct-current voltage.

In a further aspect, a three-terminal back-end-of-line compatible ferroelectric capacitive synaptic device may include a first metal electrode, a ferroelectric layer disposed on the first metal electrode, a semiconductor layer disposed on the ferroelectric layer, a second metal electrode disposed on the semiconductor layer and overlapping with the first metal electrode, and a third metal electrode disposed on the semiconductor layer and offset from the second metal electrode by a gap distance. Write operations may be performed between the first metal electrode and the second metal electrode, while read operations may be performed between the first metal electrode and the third metal electrode. The gap distance between the second metal electrode and the third metal electrode may be in a range of 100 nm to 200 nm.

In some cases, methods of operating these devices may involve applying positive voltage pulses to program a high capacitance state and negative voltage pulses to erase to a low capacitance state, with the capability to read the capacitance state at zero direct-current voltage. The programming and erasing operations may switch the semiconductor layer between inversion mode and depletion mode by flipping dipole orientation in the ferroelectric layer.

Capacitive crossbar arrays may comprise multiple back-end-of-line compatible ferroelectric capacitive synaptic devices arranged in rows and columns, with each device configured to switch between high and low capacitance states for in-memory computing applications. These arrays may be configured for multi-tier three-dimensional stacking on top of CMOS substrate circuits and may provide dynamic power consumption for artificial intelligence hardware applications.

The foregoing general description of the illustrative embodiments and the following detailed description thereof are merely exemplary aspects of the teachings of this disclosure and are not restrictive.

### BRIEF DESCRIPTION OF FIGURES

Non-limiting and non-exhaustive examples are described with reference to the following figures.

FIGS. 1A-F illustrate various configurations of a ferroelectric device structure, according to aspects of the present disclosure.

FIGS. 2A-2C depict a ferroelectric device structure with variable gate offset and capacitive performance characteristics, according to an embodiment. FIG. 2A depicts a device structure with variable gate offset between the second metal electrode and the third metal electrode. FIG. 2B depicts a capacitance-voltage graph showing C-V characteristics with increasing gate offset. FIG. 2C depicts simulation data summarizing capacitive performance metrics for different gate offset values.

FIGS. 3A-3C illustrate a fabrication process sequence and device structure for a back-end-of-line compatible ferroelectric capacitive synaptic device, according to an embodiment. FIG. 3A depicts a cross-sectional schematic view of the device structure. FIG. 3B depicts a fabrication process sequence. FIG. 3C depicts optical microscope images of the fabricated device.

FIGS. 4A-4B illustrate a memory array architecture and bias schemes for capacitive synaptic device operations, according to an embodiment. FIG. 4A depicts a memory array architecture. FIG. 4B depicts bias schemes for program, erase, and read operations.

### DETAILED DESCRIPTION

The following description sets forth exemplary aspects of the present disclosure. It should be recognized, however, that such description is not intended as a limitation on the scope of the present disclosure. Rather, the description also encompasses combinations and modifications to those exemplary aspects described herein.

In-memory computing architectures have emerged as a promising approach to address the limitations of conventional computing paradigms, where processing units and memories are physically separated. Traditional architectures face bottlenecks in data transfer between processing and memory components, particularly as artificial intelligence algorithms require increasingly large datasets. The separation creates congestion and overhead in data movement, leading to reduced system throughput and energy efficiency. In-memory computing performs processing operations in the same physical location where data is stored, thereby reducing data transfer latency and power consumption while enabling high input/output parallelism through mixed-signal operations.

Capacitive synaptic devices represent an advancement in in-memory computing technology, utilizing tunable small-signal capacitance instead of conductance as weight elements in neural networks. These devices operate on charge-domain computing principles, contrasting with current-domain computing used in resistive counterparts. The capacitive approach offers several operational advantages, including reduced power consumption through elimination of static power dissipation, limited voltage drop effects due to the open-circuit nature of capacitive elements, and negligible sneak-path currents. Additionally, capacitive devices may provide compact cell areas without requiring access transistors and enable read-disturbance-free operations.

The metal-ferroelectric-semiconductor (MFS) stack structure forms the foundation of capacitive synaptic devices compatible with back-end-of-line (BEOL) fabrication processes. BEOL compatibility allows these devices to be integrated at the interconnect levels of semiconductor manufacturing, operating within thermal budget constraints typically below 400° C. This compatibility enables multi-tier three-dimensional stacking of capacitive crossbar arrays on top of complementary metal-oxide-semiconductor (CMOS) substrate circuits at interconnect levels. The three-dimensional integration capability provides enhanced integration density for storing large-capacity artificial intelligence models while maintaining compatibility with existing semiconductor manufacturing infrastructure.

The operational principle of capacitive synaptic devices relies on capacitive read-out mechanisms that differentiate between high capacitance states and low capacitance states at zero direct-current (DC) gate voltage. This zero-voltage operation eliminates the need for continuous bias voltages during read operations, contributing to the power efficiency advantages of the capacitive approach. The ferroelectric component within the MFS stack enables non-volatile storage of capacitive states through polarization switching, allowing the devices to retain their programmed states without continuous power supply. The semiconductor layer within the stack may be configured to switch between different conductive modes in response to the ferroelectric polarization state, thereby modulating the overall device capacitance.

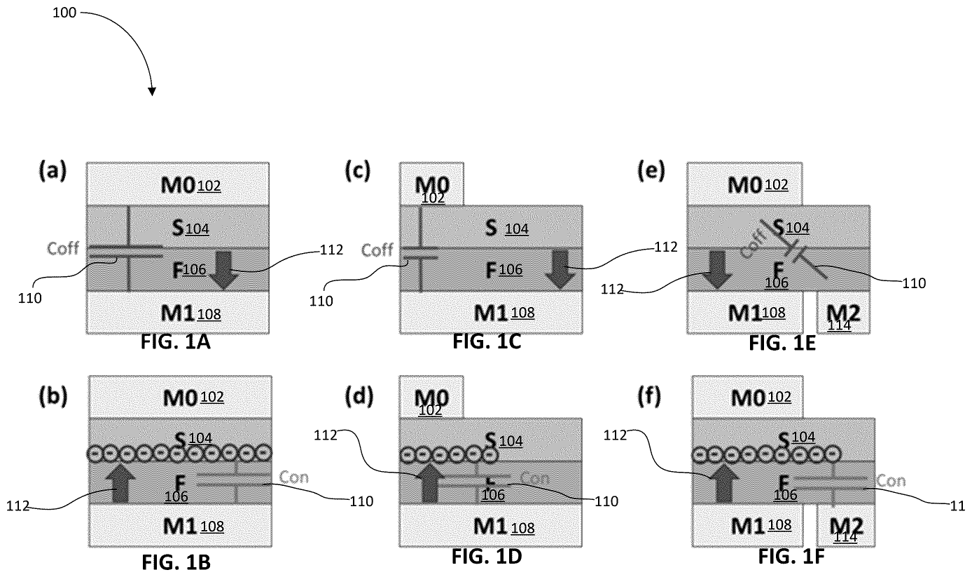

Referring to FIGS. 1A-F, a device structure 100 comprises a metal-ferroelectric-semiconductor (MFS) stack configuration that provides the foundational architecture for capacitive synaptic devices. The device structure 100 includes a first metal electrode 102, a ferroelectric layer 106 disposed on the first metal electrode 102, a semiconductor layer 104 disposed on the ferroelectric layer 106, and a second metal electrode 108 disposed on the semiconductor layer 104. This layered arrangement creates a stack where each component contributes to the overall capacitive behavior and switching characteristics of the device structure 100. The sequential arrangement of these layers allows for controlled modulation of capacitance through ferroelectric polarization switching while maintaining compatibility with semiconductor fabrication processes.

The semiconductor layer 104 may comprise various amorphous oxide semiconductor materials that provide the electronic properties for capacitive modulation. In some cases, the semiconductor layer 104 comprises amorphous silicon or polycrystalline silicon, which offer established processing compatibility and well-understood electronic characteristics. Alternatively, the semiconductor layer 104 may comprise indium-oxide variants including indium-tungsten-oxide (IWO), indium-tin-oxide (ITO), or indium-gallium-zinc-oxide (IGZO). These oxide semiconductor materials provide advantageous properties such as controlled carrier concentrations and mobility characteristics suitable for capacitive switching applications. The semiconductor layer 104 may be configured as an n-type material where carriers, following inversion for silicon-based materials or enhancement for oxide semiconductor materials, are electrons that contribute to the capacitive behavior of the device structure 100.

With continued reference to FIGS. 1A-F, the ferroelectric layer 106 provides the polarization switching capability that enables non-volatile capacitive state modulation. The ferroelectric layer 106 may comprise doped hafnia-based materials that exhibit ferroelectric properties suitable for the operating conditions of the device structure 100. In some cases, the ferroelectric layer 106 comprises hafnium-zirconium-oxide (HZO), which provides stable ferroelectric behavior and compatibility with semiconductor processing. Alternatively, the ferroelectric layer 106 may comprise silicon-doped hafnium oxide (Si:HfO₂), where the silicon doping enhances the ferroelectric characteristics and processing stability. These hafnia-based materials allow for polarization switching at voltages compatible with semiconductor device operation while maintaining the ferroelectric properties across multiple switching cycles.

The material composition and processing characteristics of the device structure 100 provide compatibility with back-end-of-line (BEOL) fabrication thermal budget temperatures below 400° C. This thermal compatibility allows the semiconductor layer 104 and ferroelectric layer 106 to maintain their electronic and ferroelectric properties during the temperature exposures encountered in BEOL processing steps. The temperature constraint influences the selection of materials for both the semiconductor layer 104 and ferroelectric layer 106, where the chosen materials retain their functional characteristics within the thermal limitations of BEOL fabrication. As shown in FIGS. 1A-F, the device structure 100 may be configured in various electrode arrangements while maintaining the fundamental MFS stack architecture and BEOL thermal compatibility across different structural variations.

Referring to FIGS. 1A-D, the device structure 100 may be configured in two distinct two-terminal arrangements that provide different operational characteristics and performance advantages. The first configuration, illustrated in FIGS. 1A-B, demonstrates a complete electrode overlap arrangement where the first metal electrode 102 and the second metal electrode 108 completely overlap with the ferroelectric layer 106 and the semiconductor layer 104 sandwiched therebetween. In this configuration, both write and read operations are performed between the first metal electrode 102 and the second metal electrode 108, creating a symmetric electrode arrangement that provides uniform electric field distribution across the ferroelectric layer 106. The complete overlap configuration allows for maximum interaction area between the electrodes and the active layers, facilitating comprehensive polarization switching throughout the ferroelectric layer 106 during programming and erasing operations.

The operational mechanism of the complete overlap configuration relies on the modulation of the semiconductor layer 104 between different conductive states through ferroelectric polarization switching. During write operations, a positive program voltage pulse applied to the second metal electrode 108 while grounding the first metal electrode 102 switches the semiconductor layer 104 to an inversion or enhancement mode by establishing upward polarization in the ferroelectric layer 106. Conversely, a negative erase voltage pulse applied to the second metal electrode 108 while grounding the first metal electrode 102 switches the semiconductor layer 104 to a depletion mode by establishing downward polarization in the ferroelectric layer 106. The polarization switching in the ferroelectric layer 106 modulates the carrier concentration in the semiconductor layer 104, thereby controlling the capacitive coupling between the electrodes and the semiconductor layer 104.

With continued reference to FIGS. 1A-B, the capacitive states of the complete overlap configuration are determined by the dominant capacitive coupling mechanisms in each polarization state. When the semiconductor layer 104 operates in the inversion or enhancement mode at zero direct-current voltage, as shown in FIG. 1B, the capacitance between the second metal electrode 108 and the semiconductor layer 104 dominates the on-state capacitance. In this state, electrons in the semiconductor layer 104 screen the first metal electrode 102, creating a high capacitance condition where the semiconductor layer 104 acts as an effective electrode. When the semiconductor layer 104 operates in the depletion mode at zero direct-current voltage, as shown in FIG. 1A, the capacitance between the first metal electrode 102 and the second metal electrode 108 dominates the off-state capacitance, where the depleted semiconductor layer 104 contributes minimal screening effect.

The second two-terminal configuration, illustrated in FIGS. 1C-D, demonstrates a partial electrode overlap arrangement where the first metal electrode 102 partially overlaps with the ferroelectric layer 106 and the semiconductor layer 104 while maintaining alignment with the second metal electrode 108 underneath. This partial overlap configuration provides an improved capacitance on/off ratio compared to the complete overlap arrangement by reducing the off-state capacitance through decreased electrode overlap area. The reduced overlap area between the first metal electrode 102 and the underlying layers creates a smaller capacitive coupling area during the off-state condition, while maintaining sufficient overlap for effective polarization switching during write operations. Both write and read operations in the partial overlap configuration are performed between the first metal electrode 102 and the second metal electrode 108, similar to the complete overlap arrangement.

As further shown in FIGS. 1C-D, the partial overlap configuration operates through the same polarization switching mechanism as the complete overlap arrangement, where voltage pulses applied between the first metal electrode 102 and the second metal electrode 108 control the ferroelectric polarization state and corresponding semiconductor layer 104 conductivity. The operational advantage of the partial overlap configuration emerges during the off-state condition, where the reduced overlap area between the first metal electrode 102 and the second metal electrode 108 creates a smaller off-state capacitance compared to the complete overlap configuration. The off-state capacitance may be proportional to the overlap area between the electrodes, allowing the partial overlap configuration to achieve lower off-state capacitance values while maintaining comparable on-state capacitance levels.

The device structure 100 in both two-terminal configurations may achieve capacitance on/off ratios greater than 1000, representing a substantial improvement over conventional metal-ferroelectric-metal capacitor structures that typically exhibit capacitance on/off ratios less than 2. This enhanced ratio performance enables the device structure 100 to provide clear differentiation between capacitive states during read operations, facilitating reliable operation in large-scale crossbar arrays. The capacitive read-out operations may be performed at zero direct-current voltage with small read voltages of approximately 0.1V, providing read-disturbance-free operation that does not affect the stored polarization state in the ferroelectric layer 106. The low-voltage read capability contributes to the power efficiency advantages of the capacitive approach while maintaining the non-volatile storage characteristics provided by the ferroelectric layer 106.

Referring to FIGS. 1E-F, the device structure 100 may be configured in a three-terminal arrangement that provides enhanced capacitive performance through separate write and read electrode terminals. The three-terminal configuration includes the first metal electrode 102, the ferroelectric layer 106 disposed on the first metal electrode 102, the semiconductor layer 104 disposed on the ferroelectric layer 106, the second metal electrode 108 disposed on the semiconductor layer 104, and a third metal electrode 110 disposed on the semiconductor layer 104. The third metal electrode 110 functions as a read metal electrode that enables independent read operations while the second metal electrode 108 serves as a write terminal for programming and erasing operations. This electrode arrangement allows the device structure 100 to optimize both write and read performance through dedicated terminal configurations that address the operational limitations of two-terminal arrangements.

The electrode positioning in the three-terminal configuration provides distinct operational advantages through controlled overlap and offset arrangements. The second metal electrode 108 overlaps substantially with the first metal electrode 102 with the ferroelectric layer 106 and the semiconductor layer 104 sandwiched therebetween, creating a large interaction area for polarization switching during write operations. The substantial overlap between the first metal electrode 102 and the second metal electrode 108 ensures comprehensive polarization switching throughout the ferroelectric layer 106, allowing for effective modulation of the semiconductor layer 104 conductivity across a large portion of the device structure 100. The third metal electrode 110 may be positioned adjacent to the second metal electrode 108 with an offset distance 200 that creates spatial separation between the write and read terminals.

With continued reference to FIGS. 1E-F, the operational mechanism of the three-terminal configuration separates write and read functions between different electrode pairs to optimize device performance. Write operations are performed between the first metal electrode 102 and the second metal electrode 108, where voltage pulses applied to the second metal electrode 108 while grounding the first metal electrode 102 control the polarization state of the ferroelectric layer 106. During programming operations, a positive voltage pulse applied to the second metal electrode 108 establishes upward polarization in the ferroelectric layer 106, switching the semiconductor layer 104 to an inversion or enhancement mode. During erasing operations, a negative voltage pulse applied to the second metal electrode 108 establishes downward polarization in the ferroelectric layer 106, switching the semiconductor layer 104 to a depletion mode. The large overlap area between the first metal electrode 102 and the second metal electrode 108 facilitates comprehensive polarization switching throughout the ferroelectric layer 106.

Read operations in the three-terminal configuration are performed between the first metal electrode 102 and the third metal electrode 110, providing operational advantages through the spatial separation from the write electrodes. The read operations may be conducted at zero direct-current voltage with small read voltages of approximately 0.1V, creating read-disturbance-free operation that does not affect the stored polarization state in the ferroelectric layer 106. The separation between write and read electrode pairs allows the read operations to sense the capacitive state without applying voltages that could disturb the ferroelectric polarization established during write operations. The third metal electrode 110 may be separated from the first metal electrode 102 by a gap that creates controlled capacitive coupling mechanisms depending on the semiconductor layer 104 conductivity state.

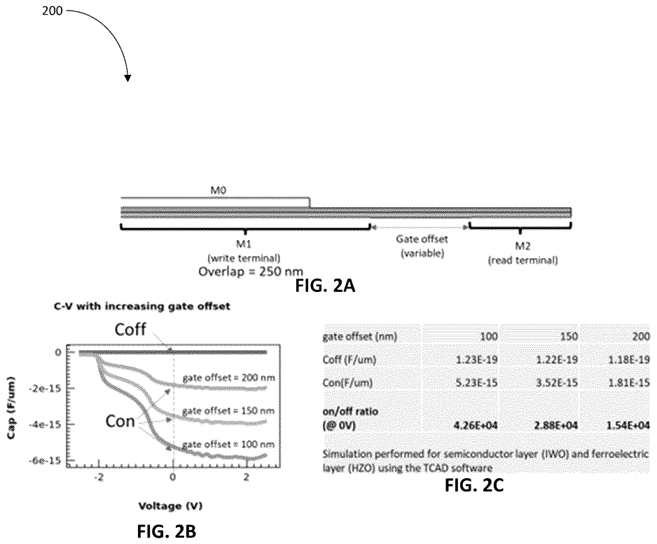

Referring to FIGS. 2A-2C, the three-terminal configuration demonstrates variable capacitive performance based on a gate offset 202 between the second metal electrode 108 and the third metal electrode 110. The gate offset 202 may range from 100 nm to 200 nm, providing different capacitive coupling characteristics and on/off ratio performance. The offset distance 200 between the second metal electrode 108 and the third metal electrode 110 influences both the on-state and off-state capacitance values through different coupling mechanisms. Technology computer-aided design simulations demonstrate the relationship between the gate offset 202 and the resulting capacitance-voltage characteristics, where the offset distance 200 affects the capacitive coupling between the third metal electrode 110 and the underlying device layers. The variable gate offset 202 allows optimization of the capacitive performance for different application requirements while maintaining the fundamental three-terminal operational principles.

As further shown in FIGS. 2A-2C, the capacitive states in the three-terminal configuration are determined by different dominant coupling mechanisms depending on the semiconductor layer 104 conductivity state. When the semiconductor layer 104 operates in an inversion or enhancement mode, the capacitance between the third metal electrode 110 and the semiconductor layer 104 dominates the on-state capacitance, where electrons in the semiconductor layer 104 provide effective screening and capacitive coupling with the third metal electrode 110. When the semiconductor layer 104 operates in a depletion mode, fringing capacitance between the third metal electrode 110 and the first metal electrode 102 dominates the off-state capacitance, where the depleted semiconductor layer 104 provides minimal screening effect. The fringing capacitance mechanism creates a much smaller off-state capacitance compared to direct electrode coupling, contributing to enhanced on/off ratio performance in the three-terminal configuration.

The three-terminal configuration provides enhanced capacitive performance through the combination of optimized write operations and controlled read coupling mechanisms. The substantial overlap between the first metal electrode 102 and the second metal electrode 108 ensures effective polarization switching throughout the ferroelectric layer 106, creating strong modulation of the semiconductor layer 104 conductivity for large on-state capacitance values. The offset distance 200 between the second metal electrode 108 and the third metal electrode 110 creates controlled fringing capacitance during off-state conditions, where the spatial separation reduces the capacitive coupling and creates lower off-state capacitance values. The combination of enhanced on-state capacitance and reduced off-state capacitance allows the three-terminal configuration to achieve capacitance on/off ratios that may exceed the performance of two-terminal arrangements while maintaining read-disturbance-free operation through the separated read electrode configuration.

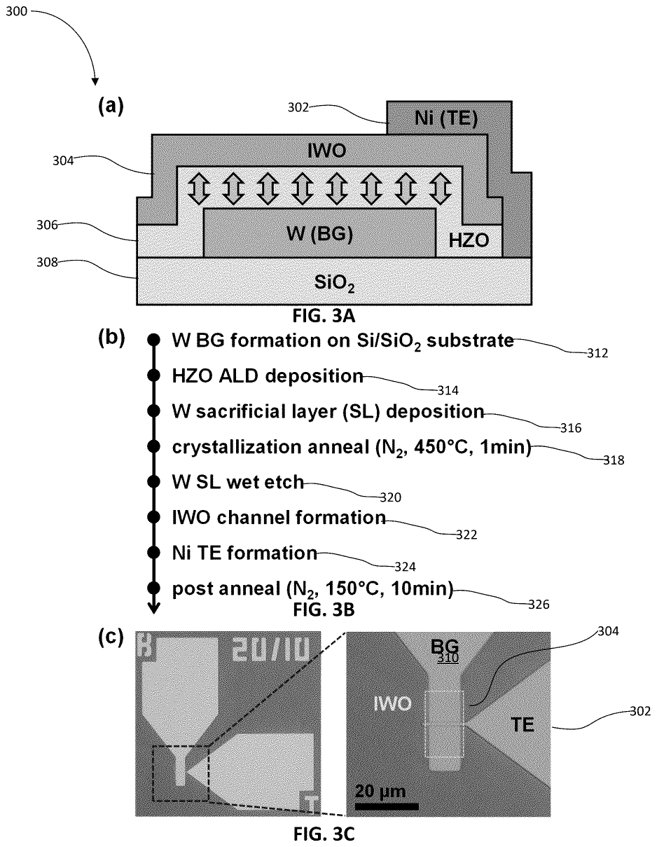

Referring to FIGS. 3A-3C, a fabrication process sequence 300 demonstrates the back-end-of-line compatible manufacturing approach for the ferroelectric capacitive synaptic device structure. The fabrication process sequence 300 begins with a Si/SiO2 substrate 310 that provides the foundational platform for device construction. The substrate 310 may comprise standard silicon wafer materials with thermally grown or deposited silicon dioxide layers that are compatible with conventional semiconductor processing infrastructure. The Si/SiO2 substrate 310 provides mechanical support and electrical isolation for the subsequent device layers while maintaining compatibility with complementary metal-oxide-semiconductor fabrication processes.

The fabrication process sequence 300 proceeds through a series of controlled deposition and patterning steps that create the metal-ferroelectric-semiconductor stack structure. The W BG formation step 312 establishes the W bottom gate 306 through tungsten deposition and patterning processes that define the first metal electrode 102 geometry. The tungsten material provides low resistance electrode characteristics and thermal stability suitable for the subsequent processing steps. Following the bottom electrode formation, the HZO deposition step 314 creates the HZO layer 304 through atomic layer deposition techniques that provide precise thickness control and uniform coverage across the substrate surface. The hafnium-zirconium-oxide composition of the HZO layer 304 provides the ferroelectric properties while maintaining compatibility with the thermal budget constraints of back-end-of-line processing.

The fabrication process sequence 300 incorporates a sacrificial layer approach through the W sacrificial layer deposition step 316 that facilitates controlled processing of the ferroelectric layer. The crystallization anneal step 318 applies thermal treatment at a crystallization temperature 450 of 450° C. for one minute in nitrogen ambient to establish the ferroelectric phase in the HZO layer 304. This annealing temperature remains within the thermal budget limitations of back-end-of-line processing while providing sufficient thermal energy to promote the formation of the orthorhombic crystal phase that exhibits ferroelectric behavior. The W SL wet etch step 320 removes the sacrificial tungsten layer through selective etching processes that preserve the underlying ferroelectric layer integrity.

The completion of the fabrication process sequence 300 involves the formation of the semiconductor and top electrode layers through controlled deposition processes. The IWO channel formation step 322 creates the IWO channel 302 comprising indium-tungsten-oxide material that serves as the semiconductor layer 104 in the device structure. The indium-tungsten-oxide composition provides n-type semiconductor characteristics with controlled carrier concentration and mobility properties suitable for capacitive modulation applications. The Ni TE formation step 324 establishes the Ni top electrode 308 through nickel deposition and patterning processes that define the second metal electrode 108 geometry. The fabrication process sequence 300 concludes with the post anneal step 326 that applies thermal treatment at a post anneal temperature 150 of 150° C. for ten minutes in nitrogen ambient to optimize the interface properties and device performance characteristics while maintaining the thermal budget compatibility required for back-end-of-line integration.

Capacitive synaptic devices may be implemented in crossbar array configurations to enable in-memory computing applications that address the limitations of conventional computing architectures. A capacitive crossbar array comprises a plurality of capacitive synaptic devices arranged in a crossbar configuration, where individual devices are positioned at the intersections of row and column conductors to form a matrix structure. Each capacitive synaptic device within the crossbar array comprises a metal-ferroelectric-semiconductor stack structure compatible with BEOL fabrication processes, allowing the array to be integrated at the interconnect levels of semiconductor manufacturing. The crossbar configuration enables parallel access to multiple capacitive synaptic devices simultaneously, facilitating high-throughput operations for neural network computations and artificial intelligence applications.

The crossbar array architecture provides operational advantages through the arrangement of capacitive synaptic devices in rows and columns that enable matrix-vector multiplication operations. In some cases, the row conductors may serve as input lines that carry voltage signals representing input data, while the column conductors may serve as output lines that accumulate charge responses from multiple capacitive synaptic devices. The capacitive synaptic devices at each crossbar intersection store weight values through their programmable capacitance states, allowing the array to perform weighted sum operations that form the foundation of neural network computations. The crossbar arrangement enables parallel processing of multiple input-weight combinations simultaneously, providing computational efficiency advantages over sequential processing approaches.

The capacitive crossbar array may be configured for charge-domain computing operations using tunable small-signal capacitance as weights in neural networks. During computation operations, input voltage pulses applied to row conductors create charge transfer through the capacitive synaptic devices based on their programmed capacitance values. The charge responses from multiple devices connected to each column conductor accumulate to produce output signals that represent the weighted sum of input values. The charge-domain approach contrasts with current-domain computing used in resistive crossbar arrays, where the capacitive elements provide controlled charge transfer rather than continuous current flow. The tunable capacitance values of individual capacitive synaptic devices enable precise control of weight magnitudes in neural network operations.

Power consumption characteristics of capacitive crossbar arrays provide substantial advantages over resistive counterparts through the elimination of static power dissipation. The capacitive crossbar array may be configured to consume only dynamic power during operation while eliminating static power consumption that occurs in resistive implementations. Capacitive elements within the array consume power only during charge and discharge transitions at the rising and falling edges of input voltage pulses, creating transient current flow that ceases once the capacitive elements reach steady-state conditions. In contrast, resistive crossbar arrays maintain continuous current flow through resistive elements whenever input voltages are applied, creating static power consumption that persists throughout the duration of high input voltage states. The dynamic-only power consumption of capacitive arrays reduces overall energy requirements for neural network computations.

The power savings achieved through capacitive crossbar array implementation may provide substantial improvements over conventional resistive approaches. In some cases, the capacitive crossbar array provides power savings of 10X to 100X compared to resistive crossbar arrays that employ conventional resistive random access memory or magnetic random access memory elements. The power reduction stems from the elimination of static current paths through the capacitive elements, where the open-circuit nature of capacitors prevents continuous current flow during steady-state conditions. The magnitude of power savings depends on the duty cycle and operating frequency of the neural network computations, where applications with longer hold times for input signals achieve greater power reduction benefits through the elimination of static power consumption during these periods.

Operational advantages of capacitive crossbar arrays extend beyond power consumption to include improved signal integrity and reduced interference effects. The capacitive crossbar array may be configured for read-disturbance-free operations that do not affect the stored capacitive states during sensing operations. Read operations may be performed at zero direct-current voltage with small read voltages that do not disturb the ferroelectric polarization states within the capacitive synaptic devices. The read-disturbance-free characteristic enables reliable operation in large-scale arrays where multiple read operations may occur simultaneously without affecting the stored weight values in neighboring devices. The capacitive crossbar array may exhibit negligible sneak-path currents due to the open-circuit nature of the capacitive elements, where the high impedance of capacitive devices prevents unwanted current paths through unselected devices in the array.

Integration density advantages of capacitive crossbar arrays emerge through compatibility with multi-tier three-dimensional stacking architectures. The capacitive crossbar array may be configured for multi-tier three-dimensional stacking on top of CMOS substrate circuits at interconnect levels to provide high integration density for artificial intelligence hardware applications. The BEOL compatibility of the capacitive synaptic devices enables vertical stacking of multiple crossbar array layers above the CMOS substrate without interfering with the underlying transistor structures. Each stacked layer may contain a complete crossbar array with independent addressing and control circuitry, allowing the three-dimensional structure to store large-capacity artificial intelligence models within a compact footprint. The multi-tier stacking capability enables scaling of neural network capacity through vertical integration rather than lateral expansion.

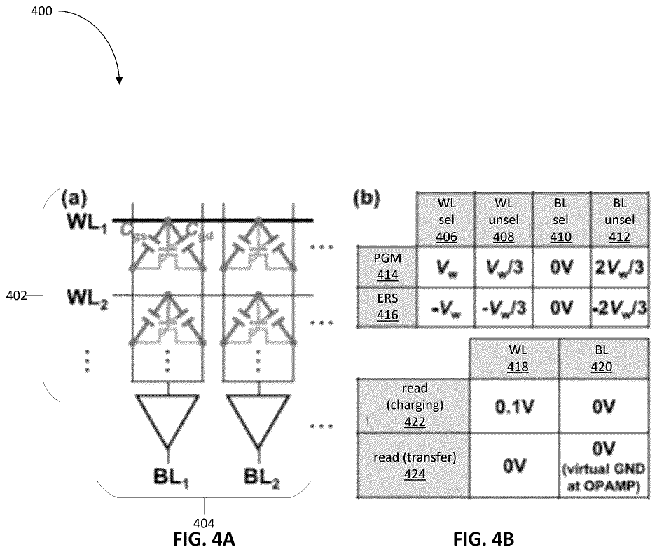

Referring to FIGS. 4A-4B, a memory array architecture and bias schemes demonstrate the operational implementation of capacitive synaptic devices in crossbar array configurations for in-memory computing applications. FIG. 4A illustrates a memory array 400 comprising a wordline group 402 and a bitline group 404 that form the fundamental structure for accessing and controlling individual capacitive synaptic devices within the array. The wordline group 402 includes multiple wordlines such as WL1 and WL2 that serve as row conductors for addressing specific rows of capacitive synaptic devices. The bitline group 404 comprises column conductors including BL1 and BL2 that enable parallel access to devices within each column of the array. Each intersection of wordlines and bitlines contains a capacitive synaptic device that stores weight information through its programmable capacitance state.

The memory array 400 incorporates operational amplifiers and reference capacitors at the bottom of each bitline to facilitate charge-domain readout operations. Each column includes an operational amplifier connected to a reference capacitor (Cref) that enables the conversion of accumulated charge from multiple capacitive synaptic devices into measurable voltage signals. The operational amplifiers provide high input impedance characteristics that minimize loading effects on the capacitive elements while amplifying the small charge signals generated during computation operations. The reference capacitors establish baseline capacitance values that enable differential sensing and improve the signal-to-noise ratio of the readout circuitry.

FIG. 4B presents the bias schemes for program, erase, and read operations that control the capacitive states of individual devices within the memory array 400. During program mode 414, a selected wordline 406 receives a program voltage Vw while unselected wordlines 408 receive Vw/3 to minimize disturbance effects on non-selected devices. The selected bitline 410 may be grounded at 0V while unselected bitlines 412 receive 2Vw/3 to create the appropriate voltage differentials for programming operations. During erase mode 416, the voltage polarities are reversed with the selected wordline 406 receiving-Vw and unselected wordlines 408 receiving −Vw/3, while the bitline voltages follow similar patterns with opposite polarity. These bias schemes ensure that only the device at the intersection of the selected wordline and bitline experiences the full programming or erasing voltage, while other devices in the array experience reduced voltages that do not affect their stored states.

The read operations utilize a two-phase approach comprising charging and transfer phases that enable charge-domain sensing of the capacitive states. During the charging phase, a charging wordline 418 receives a small voltage of 0.1V while the transfer wordline 420 remains at 0V, and the bitline voltage is maintained at 0V. This charging phase allows the capacitive synaptic devices to accumulate charge based on their programmed capacitance values. During the transfer phase, both wordlines are set to appropriate voltages while the bitline is connected to the virtual ground of the operational amplifier, enabling the accumulated charge to transfer to the reference capacitor for voltage conversion. The two-phase read approach provides read-disturbance-free operation by using small read voltages that do not affect the ferroelectric polarization states of the capacitive synaptic devices.

The three-dimensional integration approach provides advantages for artificial intelligence hardware applications that require large numbers of synaptic connections and weight storage capacity. In some cases, individual crossbar array layers may be dedicated to different portions of neural network architectures, such as convolutional layers, fully connected layers, or recurrent structures. The vertical stacking enables hierarchical organization of neural network computations where data may flow between different crossbar array layers through vertical interconnections. The integration density achieved through multi-tier stacking allows artificial intelligence hardware to accommodate complex neural network models while maintaining compatibility with standard semiconductor packaging and thermal management approaches. The BEOL fabrication compatibility ensures that the three-dimensional capacitive crossbar arrays may be manufactured using established semiconductor processing techniques without requiring specialized fabrication equipment or processes.

A number of implementations have been described. Nevertheless, it will be understood that various modifications may be made without departing from the spirit and scope of the disclosure. Accordingly, other implementations are within the scope of the following claims.

1. A back-end-of-line (BEOL) compatible ferroelectric capacitive synaptic device comprising:
a first metal electrode;
a ferroelectric layer disposed on the first metal electrode;
a semiconductor layer disposed on the ferroelectric layer, wherein the semiconductor layer comprises a material compatible with a back-end-of-line fabrication thermal budget temperature; and
a second metal electrode disposed on the semiconductor layer,
wherein:
the first metal electrode and the second metal electrode completely overlap with the ferroelectric layer and the semiconductor layer sandwiched therebetween, and
the BEOL compatible ferroelectric capacitive synaptic device is configured to switch between a high capacitance state and a low capacitance state by applying voltage pulses between the first metal electrode and the second metal electrode to flip dipole orientation in the ferroelectric layer.

2. The BEOL compatible ferroelectric capacitive synaptic device of claim 1, wherein the semiconductor layer comprises an amorphous oxide semiconductor material selected from the group consisting of amorphous silicon, polycrystalline silicon, indium-tungsten-oxide, indium-tin-oxide, and indium-gallium-zinc-oxide.

3. The BEOL compatible ferroelectric capacitive synaptic device of claim 1, wherein the ferroelectric layer comprises a doped hafnia-based material selected from a group comprised of hafnium-zirconium-oxide and silicon-doped hafnium oxide.

4. The BEOL compatible ferroelectric capacitive synaptic device of claim 1, wherein in the high capacitance state, capacitance between the second metal electrode and the semiconductor layer dominates, and in the low capacitance state, capacitance between the first metal electrode and the second metal electrode dominates.

5. A back-end-of-line (BEOL) compatible ferroelectric capacitive synaptic device comprising:
a first metal electrode;
a ferroelectric layer disposed on the first metal electrode;
a semiconductor layer disposed on the ferroelectric layer, wherein the semiconductor layer comprises a material compatible with a back-end-of-line fabrication thermal budget temperature; and
a second metal electrode disposed on the semiconductor layer,
wherein:
the second metal electrode partially overlaps with the ferroelectric layer and the semiconductor layer, creating a reduced overlap area compared to the first metal electrode, and
the BEOL compatible ferroelectric capacitive synaptic device is configured to switch between a high capacitance state and a low capacitance state by applying voltage pulses between the first metal electrode and the second metal electrode to flip dipole orientation in the ferroelectric layer.

6. The BEOL compatible ferroelectric capacitive synaptic device of claim 5, wherein the device provides a capacitance on/off ratio greater than 1000 at zero direct-current voltage.

7. The BEOL compatible ferroelectric capacitive synaptic device of claim 5, wherein the semiconductor layer comprises an amorphous oxide semiconductor material selected from a group comprised of amorphous silicon, polycrystalline silicon, indium-tungsten-oxide, indium-tin-oxide, and indium-gallium-zinc-oxide.

8. The BEOL compatible ferroelectric capacitive synaptic device of claim 5, wherein the ferroelectric layer comprises a doped hafnia-based material selected from a group comprised of hafnium-zirconium-oxide and silicon-doped hafnium oxide.

9. A back-end-of-line (BEOL) compatible ferroelectric capacitive synaptic device comprising:
a first metal electrode;
a ferroelectric layer disposed on the first metal electrode;
a semiconductor layer disposed on the ferroelectric layer, wherein the semiconductor layer comprises a material compatible with a back-end-of-line fabrication thermal budget temperature;
a second metal electrode disposed on the semiconductor layer and overlapping with the first metal electrode; and
a third metal electrode disposed on the semiconductor layer and offset from the second metal electrode by a gap distance,
wherein:
write operations are performed between the first metal electrode and the second metal electrode, and read operations are performed between the first metal electrode and the third metal electrode, and
the device is configured to switch between a high capacitance state and a low capacitance state by applying voltage pulses between the first metal electrode and the second metal electrode to flip dipole orientation in the ferroelectric layer.

10. The BEOL compatible ferroelectric capacitive synaptic device of claim 9, wherein the gap distance between the second metal electrode and the third metal electrode is in a range of 100 nm to 200 nm.

11. The BEOL compatible ferroelectric capacitive synaptic device of claim 9, wherein in the high capacitance state, capacitance between the third metal electrode and the semiconductor layer dominates, and in the low capacitance state, fringing capacitance between the first metal electrode and the third metal electrode dominates.

12. The BEOL compatible ferroelectric capacitive synaptic device of claim 9, wherein the device provides a capacitance on/off ratio greater than 1000 at zero direct-current voltage.

13. The BEOL compatible ferroelectric capacitive synaptic device of claim 9, wherein the semiconductor layer comprises an amorphous oxide semiconductor material selected from a group comprised of amorphous silicon, polycrystalline silicon, indium-tungsten-oxide, indium-tin-oxide, and indium-gallium-zinc-oxide.

14. The BEOL compatible ferroelectric capacitive synaptic device of claim 9, wherein the ferroelectric layer comprises a doped hafnia-based material selected from a group comprised of hafnium-zirconium-oxide and silicon-doped hafnium oxide.

15. A method of operating a back-end-of-line (BEOL) compatible ferroelectric capacitive synaptic device, the method comprising:
providing a device having a first metal electrode, a ferroelectric layer, a semiconductor layer, and a second metal electrode arranged in a stack configuration;
applying a positive voltage pulse to the second metal electrode while grounding the first metal electrode to program the device with a high capacitance state; and
applying a negative voltage pulse to the second metal electrode while grounding the first metal electrode to erase the device to a low capacitance state,
wherein the semiconductor layer comprises a material compatible with a back-end-of-line fabrication thermal budget temperature.

16. The method of claim 15, further comprising reading the capacitance state of the device at zero direct-current voltage.

17. The method of claim 15, wherein the programming and erasing operations switch the semiconductor layer between inversion mode and depletion mode by flipping dipole orientation in the ferroelectric layer.

18. A capacitive crossbar array comprising:
a plurality of back-end-of-line (BEOL) compatible ferroelectric capacitive synaptic devices arranged in rows and columns, each of the BEOL compatible ferroelectric capacitive synaptic devices comprising:
a first metal electrode;
a ferroelectric layer disposed on the first metal electrode;
a semiconductor layer disposed on the ferroelectric layer, wherein the semiconductor layer comprises a material compatible with a back-end-of-line fabrication thermal budget temperature; and
a second metal electrode disposed on the semiconductor layer,
wherein each of the BEOL compatible ferroelectric capacitive synaptic devices are configured to switch between a high capacitance state and a low capacitance state for in-memory computing applications.

19. The capacitive crossbar array of claim 18, wherein the array is configured for multi-tier three-dimensional stacking on top of CMOS substrate circuits.

20. The capacitive crossbar array of claim 18, wherein the array provides dynamic power consumption for artificial intelligence hardware applications.
